(19) United States
(12) Patent Application Publication
(10) Pub. No.: US 2016/0246156 A1
(43) Pub. Date: Aug. 25, 2016

(54) OPTICAL MODULE

(71) Applicant: Fujitsu Optical Components Limited, Kawasaki-shi (JP)

(72) Inventors: Masaki Sugiyama, Sagamihara (JP); Akira Ishii, Yokohama (JP); Norihisa Naganuma, Yokohama (JP); Eiichi Kodera, Yokohama (JP)

(21) Appl. No.: 14/984,517

(22) Filed: Dec. 30, 2015

(30) Foreign Application Priority Data
Feb. 23, 2015 (JP) 2015-033388

(51) Int. Cl. G02F 1/225; H05K 1/11

(52) U.S. Cl. CPC G02F 1/2255; H05K 1/115

(57) ABSTRACT

A first circuit board has an electrode pattern, a ground pattern, a first through hole, and a second through hole. The first through hole penetrates through the electrode pattern. The second through hole penetrates through the ground pattern. A second circuit board has a signal line, an electrode terminal, and a ground terminal. The electrode terminal is extended from the signal line, and is electrically connected to the electrode pattern with the electrode terminal being inserted into the first through hole. The ground terminal is electrically connected to the ground pattern with the ground terminal being inserted into the second through hole, and has a width, a length, or an area or any combination thereof larger than a width, a length, or an area or any combination thereof of the electrode terminal.

### CROSS-REFERENCE TO RELATED APPLICATION

This application is based upon and claims the benefit of priority of the prior Japanese Patent Application No. 2015-033388, filed on Feb. 23, 2015, the entire contents of which are incorporated herein by reference.

### FIELD

The embodiment discussed herein is related to an optical module.

### BACKGROUND

In recent years, along with the increase in the capacity of optical transmission systems, for optical modules of optical modulators and the like, scale of their configurations is increasing, together with the increase in their modulation speed. Therefore, an optical transmitter equipped with an optical module is desirably downsized by integration of a plurality of Mach-Zehnders forming optical waveguides into a single chip. In the optical module, the optical waveguides are parallelly formed of, for example, four Mach-Zehnders, and on each waveguide, two strips of a signal electrode and a ground electrode are patterned. The optical module generates a signal of multi-level modulation by input of different electric signals to the two signal electrodes. In such an optical module, in order to simplify mounting of input units and reduce the mounting area, the input units for all electric signals are arranged on one side of the package.

In an optical module having input units arranged on one side thereof, electric signals, such as radio frequency (RF) signals, are input via a coaxial connector provided on a side surface of the package. Further, a coaxial adapter for inputting the electric signals from outside is connected to the coaxial connector. However, in the optical module, since a pitch between the signal electrodes, to which the electric signals are input, needs to be widened according to the width of the coaxial adapter, when the number of channels is increased, the mounting area is increased along therewith.

In order to suppress the above described increase in the mounting area, a surface mounted type optical module, to which electric signals are input from a printed circuit board (PCB) side via a flexible printed circuit (FPC) provided in the package, has been developed. In such an optical module, in order to input electric signals, an electrode pattern on the PCB is connected to an electrode pad on the FPC via solder. Thereby, the coaxial adapter is able to be removed from the optical module, and thus the pitch between the signal electrodes, to which the electric signals are input, is able to be narrowed and the mounting area is able to be decreased. As a result, the optical transmitter is able to be downsized.

However, since the electrode pattern on the PCB is connected to the electrode pad on the FPC by soldering work in a state where the FPC has been bent along the PCB, correspondingly with the bending of the FPC, the mounting area is increased. In order to prevent this, a structure for electrically connecting the PCB to the FPC without bending of the FPC has been developed. In a surface mounted type optical module adopting this structure, in a state where an electrode terminal extended from a signal pattern on an FPC has been inserted into a through hole provided in an electrode pattern on a PCB, the electrode terminal is connected to the electrode pattern on the PCB via solder. Thereby, since the FPC is not bent in this optical module, increase in the mounting area accompanying bending of the FPC is able to be suppressed (see, for example, Japanese Laid-open Patent Publication No. 04-286808).

In an FPC, two ground terminals are parallelly arranged to interpose a single electrode terminal extended from a signal pattern on the FPC. A width, a length, and an area of the signal pattern on the FPC are set, such that characteristic impedance at a connecting portion between the PCB and the FPC becomes an ideal value, 50Ω. Widths, lengths, and areas of the electrode terminal and the ground terminals are set, similarly to the signal pattern, such that characteristic impedance at the above mentioned connecting portion becomes 50Ω, and the widths, lengths, and areas are set to design values that are the same between the electrode terminal and the ground terminals. Further, the ground terminals are connected to the ground pattern on the PCB via solder with the ground terminals being inserted into through holes provided in the ground pattern on the PCB.

Therefore, the width, length, and area of the ground terminals are desirably large to a certain extent, in order to prevent the ground terminals from being detached from the ground pattern on the PCB. However, since the widths, lengths, and areas are set to the same design values between the electrode terminal and the ground terminals, the larger the width, length, and area of the ground terminals are, the larger the width, length, and area of the electrode terminal become. If the width, length, and area of the electrode terminal are too large, the width, length, and area will steeply change at a boundary between the electrode terminal and the signal pattern, and at this changing point, mismatch of impedances will occur. This mismatch is a factor that causes the characteristic impendence at the connecting portion between the PCB and FPC to be deviated from the ideal value, 50Ω. In particular, in an optical module, such as an optical modulator, which handles high frequency signals, the above described mismatch of impedances increases reflection of the high frequency signals, and as a result, the high frequency characteristics are deteriorated.

In contrast, if the width, length, and area of the electrode terminal are too small, the electrode terminal will not be strongly connected to the electrode pattern on the PCB via the solder, and thus strength of the connecting portion between the PCB and FPC will not be ensured.

### SUMMARY

According to an aspect of an embodiment, an optical module includes a first circuit board having: an electrode pattern; a ground pattern arranged on both sides of the electrode pattern; a first through hole penetrating through the electrode pattern; and a second through hole penetrating through the ground pattern; and a second circuit board having: a signal line; an electrode terminal that is extended from the signal line and is electrically connected to the electrode pattern with the electrode terminal being inserted into the first through hole; and a ground terminal that is arranged on both sides of the electrode terminal, is electrically connected to the ground pattern with the ground terminal being inserted into the second through hole, and has a width, length, or an area or any combination thereof larger than a width, length, or an area or any combination thereof of the electrode terminal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a top view illustrating a configuration of an optical module according to an embodiment;

FIG. 2 is a partial cross sectional view illustrating an example of a connecting portion between a PCB and an FPC according to the embodiment;

FIG. 3 is an enlarged cross sectional view illustrating the example of the connecting portion between the PCB and the FPC according to the embodiment;

FIG. 4A is a side cross sectional view illustrating the example of the connecting portion between the PCB and the FPC;

FIG. 4B is a side cross sectional view illustrating another example of the connecting portion between the PCB and the FPC;

FIG. 5 is an enlarged cross sectional view illustrating an example of the connecting portion between the PCB and the FPC according to a first modification;

FIG. 6 is an enlarged cross sectional view illustrating an example of the connecting portion between the PCB and the FPC according to a second modification;

FIG. 7 is an enlarged cross sectional view illustrating an example of the connecting portion between the PCB and the FPC according to a third modification;

FIG. 8 is an enlarged cross sectional view illustrating an example of the connecting portion between the PCB and the FPC according to a fourth modification; and

FIG. 9 is a diagram illustrating a configuration of a transmitter mounted with the optical module according to any of the embodiment and modifications.

### DESCRIPTION OF EMBODIMENT

Preferred embodiment of the present invention will be explained with reference to accompanying drawings. The disclosed techniques are not limited by this embodiment.

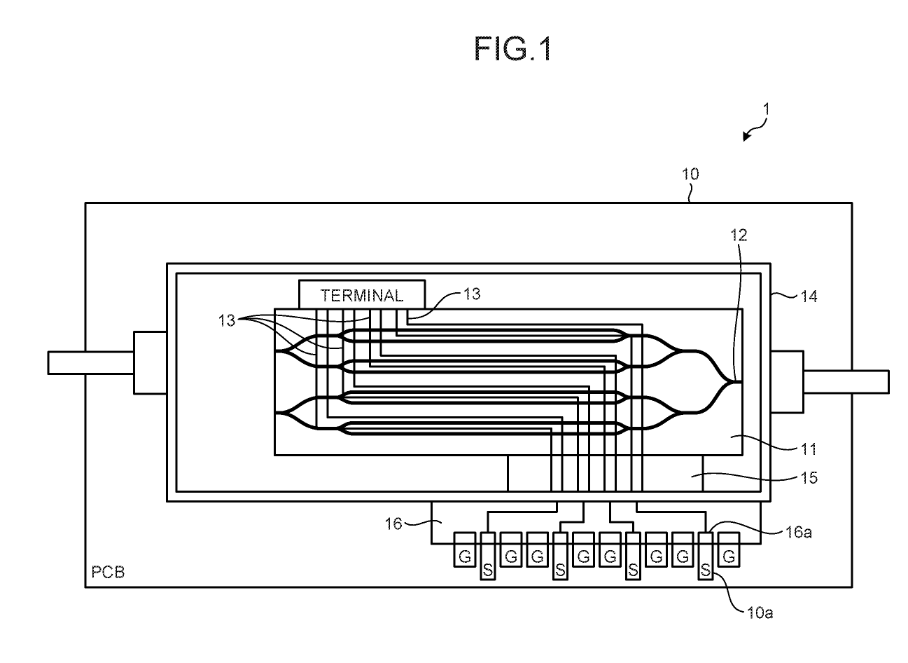

First, a configuration of an optical module according to an embodiment disclosed by this application will be described. FIG. 1 is a top view illustrating a configuration of an optical module 1 according to this embodiment. As illustrated in FIG. 1, the optical module 1 is formed by: a crystal circuit board 11 being provided on a printed circuit board (PCB) 10; and electrodes 13 being provided near optical waveguides 12 formed on the crystal circuit board 11. The PCB 10 is, for example, a glass epoxy circuit board, or the like, and is mounted with various parts forming the optical module 1. The crystal circuit board 11 is formed of an electro-optic crystal, such as LiNbO₃(LN), LiTaO₂, or the like. Further, the optical waveguides 12 are formed by forming a metal film of Ti or the like and causing the metal film to be thermally diffused, or by proton exchange in benzoic acid after patterning. The optical waveguides 12 form a Mach-Zehnder interference system, and the electrodes 13 are provided on Mach-Zehnder parallel waveguides.

Further, the electrodes 13 are arranged right on top of the optical waveguides 12 in order to use the refractive index change due to an electric field in a z-axis direction. The electrodes 13 are coplanar electrodes formed by signal electrodes and ground electrodes being patterned on the optical waveguides 12. The optical module 1 has a buffer layer between the crystal circuit board 11 and the electrodes 13, in order to prevent light propagated through the optical waveguides 12 from being absorbed by the signal electrodes and the ground electrodes. The buffer layer is formed of SiO₂ or the like, which has a thickness of about 0.2 to 2 μm.

When the optical module 1 is driven at high speed, terminals of the signal electrodes and ground electrodes are connected via a resistance to form a traveling-wave electrode, and microwave signals are applied from an input side thereof. When this is done, due to the electric field, refractive indices of the two optical waveguides 12 forming the Mach-Zehnder respectively change by +Ana and −Anb, and accompanying this, a phase difference between the optical waveguides 12 changes. As a result, signal light phase-modulated due to the Mach-Zehnder interference is output from the optical waveguides 12. By controlling an effective refractive index of microwaves by changing a cross sectional shape of the electrodes 13 and matching speeds of the light and microwaves, high speed optical response characteristics of the optical module 1 are able to be obtained.

In the optical module 1, as illustrated in FIG. 1, in a package 14 accommodating the crystal circuit board 11, optical waveguides 12, and electrodes 13, an FPC 16 is provided via a relay circuit board 15. If a high frequency propagation loss in electrodes on the FPC 16 is large, the modulation bandwidth is narrowed and the driving voltage is increased. Therefore, in order to reduce the high frequency loss in the optical module 1 handling high frequency signals, the FPC 16 is desirably made short as much as possible.

The PCB 10 is connected to the FPC 16. At a connecting portion between the PCB 10 and the FPC 16, when the FPC 16 and the PCB 10 are connected to each other via solder in a state where the FPC 16 has been bent along the PCB 10, correspondingly with the bending of the FPC 16, the mounting area is increased. In order to avoid this, in a state where an electrode terminal 16a extended from a signal pattern of the FPC 16 has been inserted into a through hole provided in an electrode pattern 10a of the PCB 10, the electrode terminal 16a is connected to the electrode pattern 10a of the PCB 10 via solder. Thereby, since the FPC 16 is not bent in this optical module 1, increase in the mounting area accompanying bending of the FPC 16 is able to be suppressed.

Further, in the optical module 1, if mismatch of impedances at the connecting portion between the PCB 10 and the FPC 16 occurs, reflection of high frequency signals is increased and the transmission frequency bandwidth is narrowed. In order to prevent this, it is important to make the impedance at the connecting portion between the electrode terminal 16a from the FPC 16 and the electrode pattern 10a of the PCB 10 to 50Ω as much as possible.

An electric signal, such as an RF signal or the like output from the electrode pattern 10a of the PCB 10 is input to the electrode 13, via the electrode terminal 16a of the FPC 16 installed in the package 14. Since the PCB 10 (electrode pattern) and the FPC 16 (electrode terminal) are connected to each other via solder, as compared to a case where a coaxial adapter is used, a pitch between the electrode terminals 16a is able to be narrowed and high density mounting is enabled.

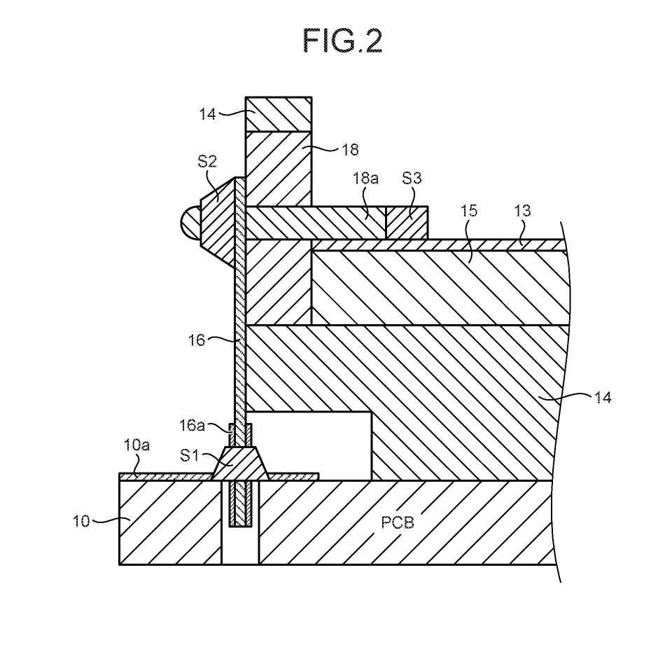

FIG. 2 is a partial cross sectional view illustrating an example of the connecting portion between the PCB 10 and the FPC 16 according to the embodiment. As illustrated in FIG. 2, the electrode pattern 10a of the PCB 10 and one end (electrode terminal 16a side) of the FPC 16 are connected to each other via a solder S1. The FPC 16 extends upward, contacts the package 14 at the other end thereof, and is fixed to a glass terminal 18 on the package 14 via a lead pin 18a and solders S2 and S3. Further, the FPC 16 is electrically connected to the relay circuit board 15 and the electrode 13 via the lead pin 18a. Thereby, after an electric signal, such as an RF signal or the like, which has been input to the electrode terminal 16a from the electrode pattern 10a, reaches the lead pin 18a via the FPC 16, the electric signal flows through the electrode 13 via the relay circuit board 15.

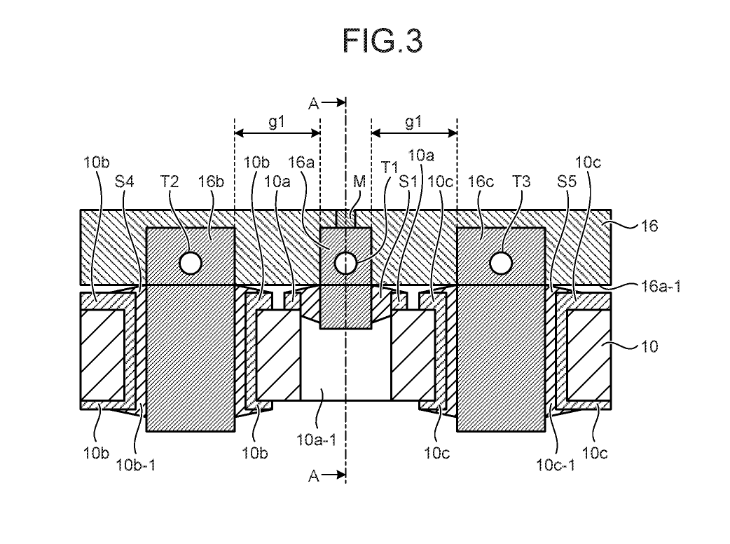

FIG. 3 is an enlarged cross sectional view illustrating the example of the connecting portion between the PCB 10 and the FPC 16 according to the embodiment. As illustrated in FIG. 3, the electrode pattern 10a is formed only on a front surface (an FPC 16 side surface) of the PCB 10 of the optical module 1 according to this embodiment. Further, on the front surface of the PCB 10, on both sides of the electrode pattern 10a, two ground patterns 10b and 10c are formed in parallel with the electrode pattern 10a. On a back surface of the PCB 10, two ground patterns 10b and 10c are formed at positions opposite to the ground patterns 10b and 10c on the front surface. That is, the electrode pattern 10a is formed only on the front surface of the PCB 10, and the ground patterns 10b and 10c are formed on the front surface and back surface of the PCB 10. Further, in the PCB 10, a through hole 10a-1 penetrating through the electrode pattern 10a, and through holes 10b-1 and 10c-1 penetrating through the ground patterns 10b and 10c are formed. The through hole 10b-1 is a through hole for electrically connecting the ground patterns 10b formed on the front surface and back surface of the PCB 10 to each other. The through hole 10c-1 is a through hole for electrically connecting the ground patterns 10c formed on the front surface and back surface of the PCB 10 to each other.

On a back surface (a package 14 side surface) of the FPC 16, a microstrip line M serving as a signal pattern is formed. Further, on a back surface of the FPC 16, the electrode terminal 16a extended from the microstrip line M is formed. Further, on the front surface of the FPC 16, on both sides of the electrode terminal 16a, two ground terminals 16b and 16c are formed in parallel with the electrode terminal 16a. Further, on the back surface of the FPC 16, an electrode terminal 16a and two ground terminals 16b and 16c are formed at positions opposite to the terminals on the front surface. That is, the electrode terminals 16a and the two ground terminals 16b and 16c are formed on the front surface and back surface of the FPC 16. The electrode terminals 16a are connected to the electrode pattern 10a formed only on the front surface of the PCB 10, via the solder S1, in a state where the electrode terminals 16a have been inserted into the through hole 10a-1 of the PCB 10. The ground terminals 16b and 16c are electrically connected to the ground patterns 10b and 10c formed on the front surface and back surface of the PCB 10 via solders S4 and S5 in a state where the ground terminals 16b and 16c have been respectively inserted into through holes, which are the through holes 10b-1 and 10c-1 of the PCB 10.

As illustrated in FIG. 3, a width, a length, and an area of the ground terminals 16b and 16c are larger than those of the electrode terminals 16a. That is, conventionally, the ground terminals 16b and 16c would have the same width, length, and area as those of the electrode terminals 16a, such that the characteristic impedance at the connecting portion between the PCB 10 and the FPC 16 would become the ideal value, 50Ω. Therefore, the greater the width, length, and area of the ground terminals 16b and 16c were, the greater the width, length, and area of the electrode terminals 16a became, and at a boundary between the electrode terminals 16a and the microstrip line M, mismatch of impedances sometimes occurred. As a result, there was a risk that reflection of high frequency signals at the connecting portion between the PCB 10 and FPC 16 might be increased and the high frequency characteristics might be deteriorated. On the contrary, if the width, length, and area of the electrode terminals 16a were too small, the electrode terminals 16a and the electrode pattern 10a of the PCB 10 would not be strongly connected to each other via the solder and thus there was a risk that strength of the connecting portion between the PCB 10 and FPC 16 would not be ensured. Therefore, the ground terminals 16b and 16c in the optical module 1 according to this embodiment have a width, a length, and an area, which are larger than those of the electrode terminals 16a. Accordingly, increase in the width, length, and area of the electrode terminals 16a is able to be suppressed, and mismatch of impedances at the connecting portion between the PCB 10 and FPC 16 is able to be suppressed. Thereby, reflection of high frequency signals at the connecting portion between the PCB 10 and FPC 16 is suppressed, and the high frequency characteristics are improved. Further, since the ground terminals 16b and 16c are connected strongly to the ground patterns 10b and 10c of the PCB 10 via solder, the strength of the connecting portion between the PCB 10 and FPC 16 is ensured. Although the width, length, and area of the ground terminals 16b and 16c are larger than those of the electrode terminals 16a in the optical module 1 illustrated in FIG. 3, at least any one of the width, length, and area of the ground terminals 16b and 16c just needs to be larger than that or those of the electrode terminals 16a.

Further, as illustrated in FIG. 3, in the electrode terminal 16a, a through hole T1, through which the solder S1 for electrically connecting the electrode terminal 16a to the electrode pattern 10a of the PCB 10 is flown, is formed. In the ground terminals 16b and 16c, through holes T2 and T3, through which the solders S4 and S5 for electrically connecting the ground terminals 16b and 16c to the ground patterns 10b and 10c of the PCB 10 are flown, are respectively formed. Thereby, the connection between the electrode terminal 16a and the electrode pattern 10a of the PCB 10, and the connection between the ground terminals 16b and 16c and the ground patterns 10b and 10c of the PCB 10 are strengthened.

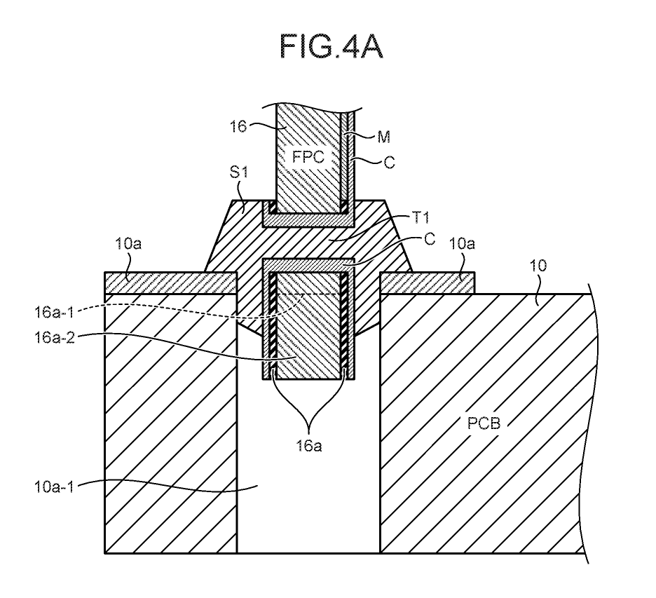

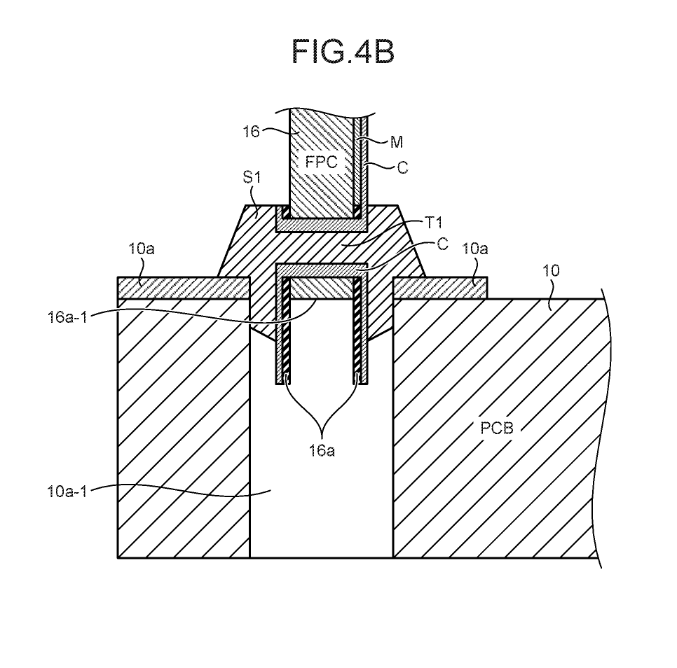

FIG. 4A is a side cross sectional view illustrating the example of the connecting portion between the PCB 10 and FPC 16. FIG. 4A corresponds to a cross sectional view along an A-A line in FIG. 3. As illustrated in FIG. 4A, the electrode terminals 16a formed on the front surface and back surface of the FPC 16 protrude over an end face 16a-1 of the FPC 16 and are inserted into the through hole 10a-1 of the PCB 10. A length of a portion of the electrode terminal 16a, the portion protruding from the end face 16a-1 of the FPC 16, is desirably less than a thickness of the PCB 10, and is desirably, for example, equal to or less than 500 μm. Further, between the electrode terminals 16a formed on the front surface and back surface of the FPC 16, a reinforcing portion 16a-2 extended from the end face 16a-1 of the FPC 16 is inserted. Thereby, bending of the electrode terminals 16a formed on the front surface and back surface of the FPC 16 is suppressed, and the connection between the electrode terminal 16a and the electrode pattern 10a of the PCB 10 is more stabilized. Further, the microstrip line M and the electrode terminals 16a of the FPC 16 are coated with a plating C in order to prevent them from being detached from the FPC 16. Furthermore, the microstrip line M and the electrode terminals 16a of the FPC 16 are desirably formed of the same material (for example, copper foil) in order to facilitate the formation thereof.

Although illustration thereof is omitted in FIG. 4A, the ground terminals 16b and 16c formed on the front surface and back surface of the FPC 16 protrude over the end face 16a-1 of the FPC 16 and are inserted into the through holes 10b-1 and 10c-1 of the PCB 10, respectively. Further, between the ground terminals 16b formed on the front surface and back surface of the FPC 16, a reinforcing portion extended from the end face 16a-1 of the FPC 16 is inserted. Furthermore, between the ground terminals 16c formed on the front surface and back surface of the FPC 16, a reinforcing portion extended from the end face 16a-1 of the FPC 16 is inserted. Thereby, bending of the ground terminals 16b and 16c formed on the front surface and back surface of the FPC 16 is suppressed, and the connection of the ground terminals 16b and 16c to the ground patterns 10b and 10c of the PCB 10 is more stabilized.

FIG. 4B is a side cross sectional view illustrating another example of the connecting portion between the PCB 10 and the FPC 16 according to the embodiment. FIG. 4B corresponds to a cross sectional view along the A-A line in FIG. 3. As illustrated in FIG. 4B, the electrode terminals 16a formed on the front surface and back surface of the FPC 16 protrude over the end face 16a-1 of the FPC 16 and are inserted into the through hole 10a-1 of the PCB 10. A length of a portion of the electrode terminal 16a is desirably less than the thickness of the PCB 10, the portion protruding from the end face 16a-1 of the FPC 16, and for example, the length is desirably equal to or less than 500 μm. Further, between the electrode terminals 16a formed on the front surface and back surface of the FPC 16, the reinforcing portion illustrated in FIG. 4A is not inserted. Thereby, the structure of the FPC 16 is simplified.

As described above, the optical module 1 has the PCB 10 and the FPC 16. The PCB 10 has the electrode pattern 10a, the ground patterns 10b and 10c, the through hole 10a-1, and the through-holes 10b-1 and 10c-1. The ground patterns 10b and 10c are arranged on both sides of the electrode pattern 10a. The through hole 10a-1 penetrates through the electrode pattern 10a. The through holes 10b-1 and 10c-1 penetrate through the ground patterns 10b and 10c. The FPC 16 has the microstrip line M, the electrode terminals 16a, and the ground terminals 16b and 16c. The electrode terminals 16a are extended from the microstrip line M, and are electrically connected to the electrode pattern 10a in a state where the electrode terminals 16a have been inserted into the through hole 10a-1. The ground terminals 16b and 16c are arranged on both sides of the electrode terminals 16a, and are electrically connected to the ground patterns 10b and 10c in a state where the ground terminals 16b and 16c have been inserted into the through holes 10b-1 and 10c-1. At least any one of the width, length, and area of the ground terminals 16b and 16c is larger than that of the electrode terminals 16a. Therefore, reflection of high frequency signals caused by mismatch of impedances at the connecting portion between the PCB 10 and FPC 16 is suppressed, and the ground terminals 16b and 16c are strongly connected to the ground patterns 10b and 10c of the PCB 10 via solder. As a result, the strength of the connecting portion between the PCB 10 and FPC 16 is able to be ensured and the high frequency characteristics are able to be improved.

### First Modification

Next, a first modification will be explained. An optical module according to the first modification has the same configuration as that of the optical module 1 according to the above described embodiment, except for that plural through holes are formed in the FPC 16. Therefore, in the first modification, the same reference signs will be used for components common to those of the above described embodiment, and detailed description thereof will be omitted.

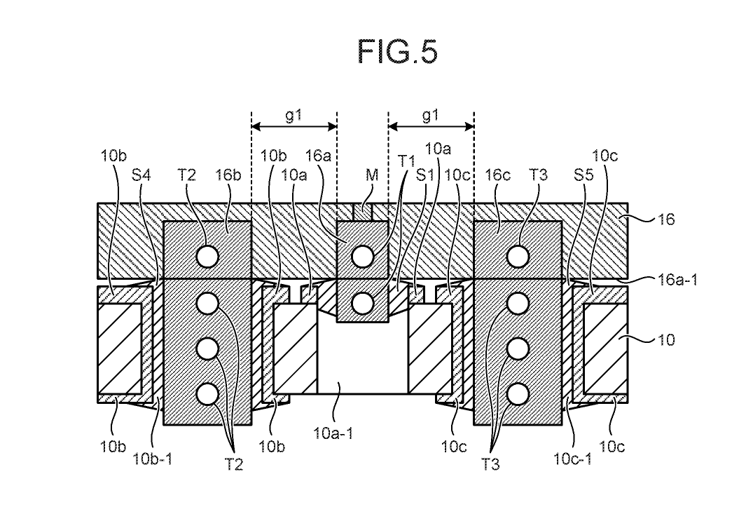

FIG. 5 is an enlarged cross sectional view illustrating an example of a connecting portion between the PCB 10 and the FPC 16 according to the first modification. As illustrated in FIG. 5, in the electrode terminal 16a of the FPC 16, plural through holes T1, through which the solder S1 for electrically connecting the electrode terminal 16a to the electrode pattern 10a of the PCB 10 is flown, are formed. In the ground terminals 16b and 16c of the FPC 16, plural through holes T2 and T3, through which the solders S4 and S5 for electrically connecting the ground terminals 16b and 16c to the ground patterns 10b and 10c of the PCB 10 are flown, are respectively formed. Thereby, the connection of the electrode terminals 16a to the electrode pattern 10a of the PCB 10, and the connection of the ground terminals 16b and 16c to the ground patterns 10b and 10c of the PCB 10 are strengthened further. As a result, strength of the connecting portion between the PCB 10 and FPC 16 is able to be increased.

### Second Modification

Next, a second modification will be explained. An optical module according to the second modification has a configuration similar to that of the optical module 1 according to the first modification, except for a shape of ground terminals of the FPC 16. Therefore, in the second modification, the same reference signs will be used for components common to those of the above described first modification, and detailed description thereof will be omitted.

In the optical module 1 according to the above described first modification, since the solder goes into the through holes T2 and T3 of the ground terminals 16b and 16c, there is concern that the characteristic impedance may be deviated from the ideal value, 50Ω. That is, when solder goes into the through holes T2 and T3 of the ground terminals 16b and 16c, correspondingly with the amount of the solder that has gone into the through holes T2 and T3, a portion of the conductive substances is increased. Therefore, there is a risk that the impedance of the portion of the through holes T2 and T3 does not match the impedance of the other portion (a portion of the ground terminals 16b and 16c not connected by the solder), and that as a result, the characteristic impedance at the connecting portion may deviate from 50Ω. Such mismatch of the impedances is a factor that increases reflection of high frequency signals and deteriorates the high frequency characteristics.

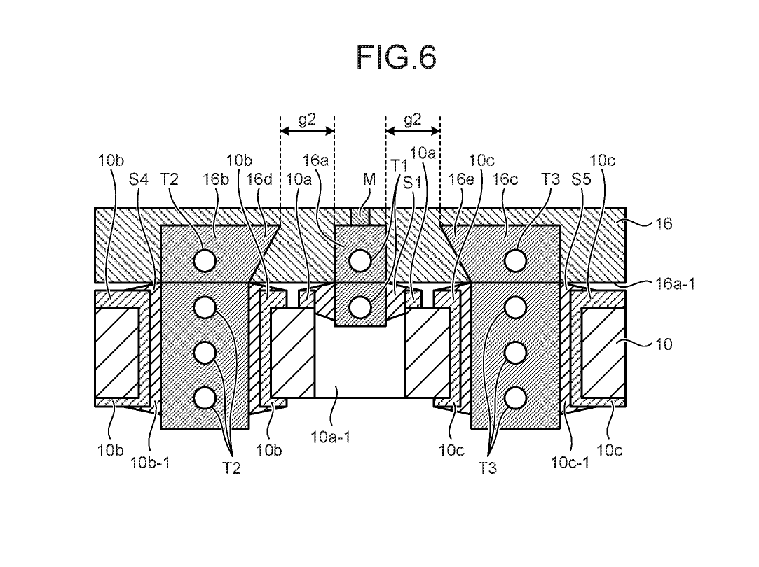

For the optical module 1 according to the second modification, adjustment of the above described impedance is aimed. FIG. 6 is an enlarged cross sectional view illustrating an example of a connecting portion between the PCB 10 and the FPC 16 according to the second modification. As illustrated in FIG. 6, the ground terminal 16b has an extended portion 16d extended towards the electrode terminal 16a from a proximal end portion of the ground terminal 16b, the proximal end portion not being inserted into the through hole 10b-1 of the PCB 10. Similarly, the ground terminal 16c has an extended portion 16e extended towards the electrode terminal 16a from a proximal end portion of the ground terminal 16c, the proximal end portion not being inserted into the through hole 10c-1 of the PCB 10. Further, a gap g2 smaller than a gap g1 in FIG. 3 is present between a distal end of the extended portion 16d on the left and the electrode terminal 16a. Similarly, a gap g2 smaller than the gap g1 in FIG. 3 is present between a distal end of the extended portion 16e on the right and the electrode terminal 16a.

Parameters for adjusting the above described characteristic impedance include, for example, an interval between a signal pattern (electrode terminal 16a) and a ground pattern (ground terminals 16b and 16c), or the like. Therefore, a manufacturer of the optical module 1 may approximate the characteristic impedance to 50Ω by adjusting the gap g2 corresponding to the interval between the signal pattern and ground pattern to an appropriate value.

As described above, in the optical module 1 according to the second modification, the ground terminals 16b and 16c have the extended portions 16d and 16e extended toward the electrode terminals 16a from the proximal end portions of the ground terminals 16b and 16c, the proximal end portions not being inserted into the through holes 10b-1 and 10c-1. Thereby, the above described mismatch of the impedances is suppressed. Therefore, reflection of high frequency signals is reduced. As a result, the high frequency characteristics are improved.

### Third Modification

Next, a third modification will be explained. An optical module according to the third modification has a configuration similar to that of the optical module 1 according to the first modification, except for a shape of electrode terminals of the FPC 16. Therefore, in the third modification, the same reference signs will be used for components common to those of the above described first modification, and detailed description thereof will be omitted.

In the optical module 1 according to the above described first modification, in order to strengthen the connection between the electrode terminal 16a of the FPC 16 and the electrode pattern 10a of the PCB 10, plural through holes, through which the solder S1 is flown, are formed in the electrode terminal 16a. However, the electrode terminals 16a are fixed only to the front surface of the PCB 10 by being electrically connected to the electrode pattern 10a formed only on the front surface of the PCB 10 via the solder S1. Therefore, if the amount of the solder S1 is small, the connection between the electrode terminals 16a of the FPC 16 and the electrode pattern 10a of the PCB 10 may be weakened. The weakening of the connection between the electrode terminals 16a of the FPC 16 and the electrode pattern 10a of the PCB 10 is a factor that reduces the strength of a connecting portion between the PCB 10 and the FPC 16.

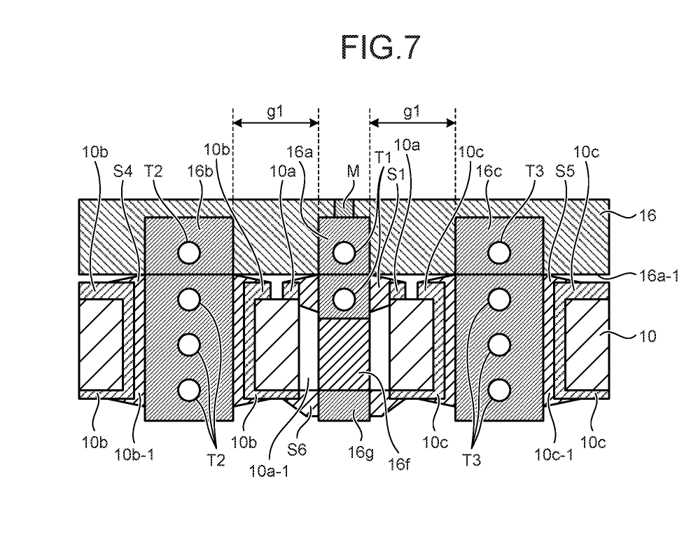

Accordingly, in the optical module 1 according to the third modification, the electrode terminals 16a are fixed, not only to the front surface of the PCB 10, but also to the back surface thereof. FIG. 7 is an enlarged cross sectional view illustrating an example of the connecting portion between the PCB 10 and the FPC 16 according to the third modification. As illustrated in FIG. 7, the electrode terminal 16a has an insulating portion 16f protruded towards an end edge of the through hole 10a-1 from a distal end portion of the electrode terminal 16a, the distal end portion being inserted into the through hole 10a-1 of the PCB 10. Further, the electrode terminal 16a has an electrode portion 16g insulated from the electrode terminal 16a by the insulating portion 16f. The electrode portion 16g is electrically connected to the ground patterns 10b and 10c formed on the back surface of the PCB 10 via a solder S6. Thereby, the connection between the electrode terminal 16a of the FPC 16 and the electrode pattern 10a of the PCB 10 is strengthened by the connection of the electrode portion 16g to the ground patterns 10b and 10c formed on the back surface of the PCB 10. As a result, strength of the connecting portion between the PCB 10 and FPC 16 is increased even further.

### Fourth Modification

Next, a fourth modification will be explained. An optical module according to the fourth modification has a configuration similar to that of the optical module 1 according to the third modification, except for a shape of electrode terminals of the FPC 16. Therefore, in the fourth modification, the same reference signs will be used for components common to those of the above described third modification, and detailed description thereof will be omitted.

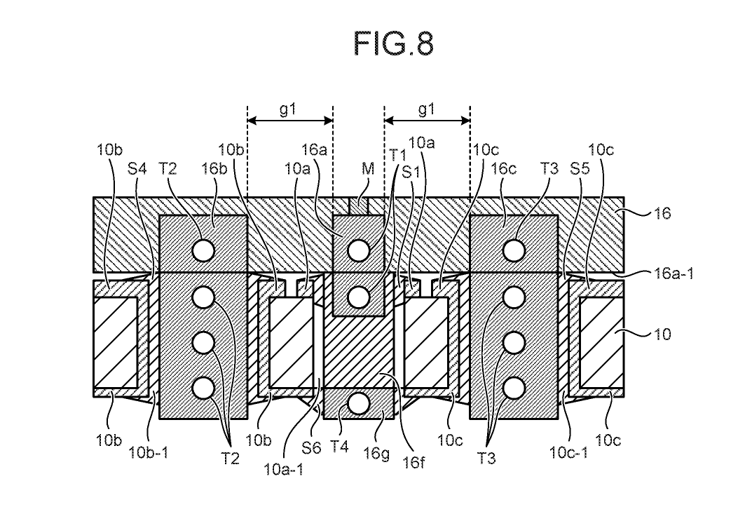

FIG. 8 is an enlarged cross sectional view illustrating an example of a connecting portion between the PCB 10 and the FPC 16 according to the fourth modification. As illustrated in FIG. 8, the insulating portion 16f and the electrode portion 16g have a width wider than that of the distal end portion of the electrode terminal 16a, the distal end portion being inserted into the through hole 10a-1 of the PCB 10. A through hole T4, through which the solder S6 for electrically connecting the electrode portion 16g to the ground patterns 10b and 10c formed on the back surface of the PCB 10 is flown, is formed in the electrode portion 16g. Thereby, the connection of the electrode portion 16g to the ground patterns 10b and 10c formed on the back surface of the PCB 10 is strengthened even further. As a result, strength of the connecting portion between the PCB 10 and FPC 16 is increased even further.

### Application Example

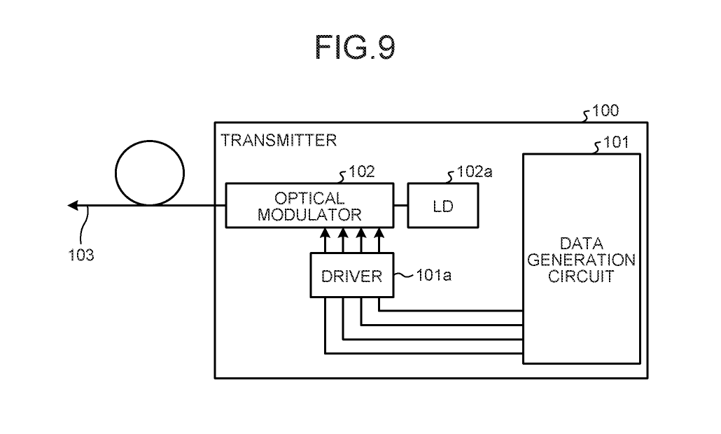

In an optical modulator using the above described optical module 1, while the strength of the connecting portion between the two circuit boards is ensured, the high frequency characteristics are able to be improved, and thus, the optical modulator is effectively applied to a transmitter, for example. FIG. 9 is a diagram illustrating a configuration of a transmitter 100 mounted with the optical module 1 according to any of the above described embodiment and modifications. As illustrated in FIG. 9, the transmitter 100 has a data generation circuit 101, an optical modulator 102, and an optical fiber 103. Further, the data generation circuit 101 has a driver 101a, and the optical modulator 102 has a laser diode (LD) 102a. These components are respectively connected to one another to be able to input and output various signals and data, unidirectionally or bidirectionally. Data generated by the data generation circuit 101 are transmitted to outside the apparatus after being converted from electric signals to optical signals by the optical modulator 102, with the optical fiber 103 being a transmission medium.

In particular, the optical module 1 is effectively applied to an optical modulator, to which an electric signal from a PCB 10 side is input by use of the FPC 16. Such optical modulators include, for example, an in-phase/quadrature (I/Q) optical modulator, a polarization multiplexed optical modulator, an ITXA, an ICR, an optical transmission and reception integrated device, and the like. Not being limited to the transmitter, the optical module 1 may be applied to a receiver.

Further, in the above description, the individual configuration and operation have been described for each of the embodiment and modifications. However, the optical module 1 according to each of the above described embodiment and modifications may also have a component specific to any of the other modifications. Further, not being limited to a combination of two of the embodiment and modifications, any mode including a combination of three or more thereof may be adopted. For example, the optical module 1 according to the second modification may have, in the electrode terminal 16a, the insulating portion 16f and the electrode portion 16g according to the third modification. Further, one optical module may have all of the components described in the above described embodiment and first to fourth modifications, as long as compatibility among them is achieved.

According to an aspect of an optical module disclosed by this application, an effect of being able to improve high frequency characteristics while ensuring strength of a connecting portion between two circuit boards is achieved.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An optical module, comprising:
a first circuit board having: an electrode pattern; a ground pattern arranged on both sides of the electrode pattern; a first through hole penetrating through the electrode pattern; and a second through hole penetrating through the ground pattern; and
a second circuit board having: a signal line; an electrode terminal that is extended from the signal line and is electrically connected to the electrode pattern with the electrode terminal being inserted into the first through hole; and a ground terminal that is arranged on both sides of the electrode terminal, is electrically connected to the ground pattern with the ground terminal being inserted into the second through hole, and has a width, length, or an area or any combination thereof larger than a width, length, or an area or any combination thereof of the electrode terminal.

2. The optical module according to claim 1, wherein
the electrode terminals are formed on a front surface and a back surface of the second circuit board,
the electrode terminals formed on the front surface and the back surface of the second circuit board protrude over an end face of the second circuit board and are inserted into the first through hole, and
a reinforcing portion extended from the end face of the second circuit board is inserted between the electrode terminals formed on the front surface and back surface of the second circuit board.

3. The optical module according to claim 1, wherein
the ground terminals are formed on a front surface and a back surface of the second circuit board,
the ground terminals formed on the front surface and the back surface of the second circuit board protrude over an end face of the second circuit board and are inserted into the second through hole, and
a reinforcing portion extended from the end face of the second circuit board is inserted between the ground terminals formed on the front surface and back surface of the second circuit board.

4. The optical module according to claim 1, wherein the electrode terminal has a through hole formed therein, through which solder for electrically connecting the electrode terminal to the electrode pattern is flown.

5. The optical module according to claim 1, wherein the ground terminal has a through hole formed therein, through which solder for electrically connecting the ground terminal to the ground pattern is flown.

6. The optical module according to claim 1, wherein the ground terminal has an extended portion extended towards the electrode terminal from a proximal end portion of the ground terminal, the proximal end portion not being inserted into the second through hole.

7. The optical module according to claim 1, wherein
the electrode pattern is formed only on a front surface of the first circuit board,
the ground patterns are formed on the front surface and a back surface of the first circuit board,
the second through hole is a through hole for electrically connecting the ground patterns formed on the front surface and the back surface of the first circuit board to each other,
the electrode terminal is electrically connected to the electrode pattern formed only on the front surface of the first circuit board with the electrode terminal being inserted into the first through hole, and
the ground terminal is electrically connected to the ground patterns formed on the front surface and the back surface of the first circuit board with the ground terminal being inserted into the second through hole.

8. The optical module according to claim 7, wherein
the electrode terminal has: an insulating portion protruded towards an end edge of the first through hole from a distal end portion of the electrode terminal, the distal end portion being inserted into the first through hole; and an electrode portion insulated from the electrode terminal by the insulating portion, and
the electrode portion is electrically connected to the ground pattern formed on the back surface of the first circuit board.

9. The optical module according to claim 8, wherein the electrode portion has a through hole formed therein, through which solder for electrically connecting the electrode portion to the ground pattern formed on the back surface of the first circuit board is flown.

10. An optical module, comprising:
an optical modulator that performs optical modulation by using an electric signal input to a plurality of electrodes from a first surface; and
a flexible circuit board that has a plurality of wiring patterns respectively connected electrically to the plurality of electrodes on the first surface and that is flexible, wherein
the flexible circuit board has: a signal line; an electrode terminal extended from the signal line; and a ground terminal that is arranged on both sides of the electrode terminal and that has a width, a length, or an area or any combination thereof larger than width, a length, or an area or any combination thereof of the electrode terminal.
